(19) United States
(12) Patent Application Publication
(10) Pub. No.: US 2023/0167552 A1
(43) Pub. Date: Jun. 1, 2023

(54) SHOWERHEAD DESIGNS FOR CONTROLLING DEPOSITION ON WAFER BEVEL/EDGE

(71) Applicant: LAM RESEARCH CORPORATION, Fremont, CA (US)

(72) Inventors: Michael J. JANICKI, Portland, OR (US); Brian Joseph WILLIAMS, Tigard, OR (US)

(21) Appl. No.: 17/921,871

(22) PCT Filed: Apr. 9, 2021
(86) PCT No.: PCT/US2021/026515

§ 371 Date: Oct. 27, 2022

Related U.S. Application Data
(60) Provisional application No. 63/041,630, filed on Jun. 19, 2020.
(60) Provisional application No. 63/016,641, filed on Apr. 28, 2020.

(51) Int. Cl. C23C 16/455; C23C 16/509; C23C 16/44; C23C 16/52

(52) U.S. Cl. CPC C23C 16/45565; C23C 16/509; C23C 16/4408; C23C 16/4558; C23C 16/52

(57) ABSTRACT

A substrate processing system includes a showerhead pedestal, a carrier ring, a showerhead, and an RF source. The showerhead pedestal includes a top surface defining a first plurality of through holes configured to output a plasma gas mixture. The carrier ring is arranged on the top surface of the showerhead pedestal to support a substrate at a predetermined distance from the top surface of the showerhead pedestal. The showerhead is arranged above the carrier ring and includes a body defining a plenum, a recessed region located on a substrate-facing surface of the body, and a second plurality of through holes extending from the plenum through the substrate-facing surface of the body in the recessed region to disperse a purge gas onto a top surface of the substrate. The RF source is configured to strike plasma between a bottom surface of the substrate and the top surface of the showerhead pedestal.

### CROSS-REFERENCE TO RELATED APPLICATIONS

This application claims the benefit of U.S. Provisional Application No. 63/016,641, filed on Apr. 28, 2020 and U.S. Provisional Application No. 63/041,630, filed on Jun. 19, 2020. The entire disclosures of the applications referenced above are incorporated herein by reference.

### FIELD

The present disclosure relates generally to substrate processing systems and more particularly to showerhead designs for controlling deposition on wafer bevel/edge.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

A substrate processing system typically includes a plurality of processing chambers (also called process modules) to perform deposition, etching, and other treatments of substrates such as semiconductor wafers. Examples of processes that may be performed on a substrate include, but are not limited to, plasma enhanced chemical vapor deposition (PECVD), chemically enhanced plasma vapor deposition (CEPVD), sputtering physical vapor deposition (PVD), atomic layer deposition (ALD), and plasma enhanced ALD (PEALD). Additional examples of processes that may be performed on a substrate include, but are not limited to, etching (e.g., chemical etching, plasma etching, reactive ion etching, etc.) and cleaning process.

During processing, a substrate is arranged on a pedestal in a processing chamber of the substrate processing system. During deposition, gas mixtures including one or more precursors are introduced into the processing chamber, and plasma is struck to activate chemical reactions. A robot typically transfers substrates from one processing chamber to another in a sequence in which the substrates are to be processed.

### SUMMARY

A substrate processing system comprises a showerhead pedestal, a carrier ring, a showerhead, and an RF source. The showerhead pedestal includes a top surface defining a first plurality of through holes configured to output a plasma gas mixture. The carrier ring is arranged on the top surface of the showerhead pedestal and is configured to support a substrate at a predetermined distance from the top surface of the showerhead pedestal. The showerhead is arranged above the carrier ring and comprises a body defining a plenum, a recessed region located on a substrate-facing surface of the body, and a second plurality of through holes extending from the plenum through the substrate-facing surface of the body in the recessed region to disperse a purge gas onto a top surface of the substrate. The RF source is configured to strike plasma between a bottom surface of the substrate and the top surface of the showerhead pedestal.

In another feature, the purge gas dispersed onto the top surface of the substrate prevents processing by the plasma from occurring on the top surface and bevel edges of the substrate.

In another feature, the purge gas prevents processing by the plasma from occurring on the top surface and bevel edges of the substrate without depleting processing by the plasma on the bottom surface of the substrate.

In other features, the body of the showerhead is cylindrical, and an outer edge of the recessed region of the showerhead tapers at an obtuse angle relative to a radius of the body toward an outer diameter of the body.

In other features, the body of the showerhead is cylindrical, and an outer edge of the recessed region of the showerhead tapers along a curve toward an outer diameter of the body.

In other features, the recessed region of the showerhead has a height. The substrate-facing surface of the body is arranged at a second distance above the carrier ring. The second distance is equal to the height.

In another feature, the substrate processing system further comprises a spacer ring arranged on the top surface of the showerhead pedestal under the carrier ring to define a gap in which to strike the plasma.

In other features, the body of the showerhead is cylindrical, and the recessed region of the showerhead is circular in shape and has a diameter that is less than or equal to a diameter of the substrate.

In other features, the body of the showerhead is cylindrical, and the recessed region of the showerhead is circular in shape and has a diameter that is greater than or equal to a diameter of the substrate.

In other features, the body of the showerhead is cylindrical, and the recessed region of the showerhead is circular in shape and has a diameter that is less than or equal to an inner diameter of the carrier ring.

In other features, the body of the showerhead is cylindrical, and the recessed region of the showerhead is circular in shape and has a diameter that is greater than or equal to an inner diameter of the carrier ring.

In another feature, the substrate-facing surface of the body contacts the carrier ring.

In another feature, the showerhead further comprises a non-recessed region located on the substrate-facing surface of the body surrounding the recessed region.

In other features, the recessed region of the showerhead is arranged above the substrate, and the non-recessed region of the showerhead is arranged above the carrier ring.

In other features, the plenum extends over the non-recessed region of the showerhead. The showerhead further comprises a third plurality of through holes extending from the plenum through the substrate-facing surface of the body in the non-recessed region to disperse the purge gas onto at least one of the substrate and the carrier ring. The substrate the body of the showerhead is cylindrical, and the non-recessed region of the showerhead is annular and has an inner diameter that is less than or equal to a diameter of the substrate. The body of the showerhead is cylindrical, and the non-recessed region of the showerhead is annular and has an inner diameter that is greater than or equal to a diameter of the substrate. The body of the showerhead is cylindrical, and the non-recessed region of the showerhead is annular and has an inner diameter that is less than or equal to an inner diameter of the carrier ring. The body of the showerhead is cylindrical, and the non-recessed region of the showerhead is annular and has an inner diameter that is greater than or equal to an inner diameter of the carrier ring.

In other features, the substrate processing system further comprises a gas distribution system to supply the purge gas to the showerhead, and a controller to control pressure of the purge gas supplied to the showerhead.

In other features, the substrate processing system further comprises an actuator to move the showerhead pedestal vertically relative to the showerhead, and a controller to control the actuator to adjust a distance between the showerhead and the carrier ring.

In still other features, a substrate processing system comprises a showerhead pedestal, a carrier ring, a showerhead, and an RF source. The showerhead pedestal includes a top surface defining a first plurality of through holes configured to output a plasma gas mixture. The carrier ring is arranged on the top surface of the showerhead pedestal and is configured to support a substrate at a predetermined distance from the top surface of the showerhead pedestal. The showerhead is arranged above the carrier ring and comprises a body defining a first plenum in fluid communication with a first inlet and a second plenum in fluid communication with a second inlet. The showerhead comprises a second plurality of through holes extending from the first plenum through a substrate-facing surface of the body to supply a purge gas at a first pressure onto a top surface of the substrate. The showerhead comprises a third plurality of through holes extending from the second plenum through the substrate-facing surface of the body to supply the purge gas at a second pressure onto the top surface of the substrate. The RF source is configured to strike plasma between a bottom surface of the substrate and the top surface of the showerhead pedestal.

In another feature, the first pressure is less than the second pressure.

In another feature, the purge gas dispersed onto the top surface of the substrate prevents processing by the plasma from occurring on the top surface and bevel edges of the substrate.

In another feature, the purge gas prevents processing by the plasma from occurring on the top surface and bevel edges of the substrate without depleting processing by the plasma on the bottom surface of the substrate.

In another feature, the substrate processing system further comprises a spacer ring arranged on the top surface of the showerhead pedestal under the carrier ring to define a gap in which to strike the plasma.

In another feature, the second plenum surrounds the first plenum.

In other features, the first plenum is arranged above the substrate, and the second plenum is arranged above the carrier ring.

In another feature, the first plenum is circular in shape and has a diameter that is less than or equal to a diameter of the substrate.

In another feature, the first plenum is circular in shape and has a diameter that is greater than or equal to a diameter of the substrate.

In another feature, the first plenum is circular in shape and has a diameter that is less than or equal to an inner diameter of the carrier ring.

In another feature, the first plenum is circular in shape and has a diameter that is greater than or equal to an inner diameter of the carrier ring.

In other features, the first plenum is circular in shape; and the second plenum is annular, surrounds the first plenum, and has an inner diameter that is less than or equal to a diameter of the substrate.

In other features, the first plenum is circular in shape; and the second plenum is annular, surrounds the first plenum, and has an inner diameter that is greater than or equal to a diameter of the substrate.

In other features, the first plenum is circular in shape; and the second plenum is annular, surrounds the first plenum, and has an inner diameter that is less than or equal to an inner diameter of the carrier ring.

In other features, the first plenum is circular in shape; and the second plenum is annular, surrounds the first plenum, and has an inner diameter that is greater than or equal to an inner diameter of the carrier ring.

In other features, geometries of the second and third plurality of through holes are different.

In other features, the substrate processing system further comprises a gas distribution system to supply the purge gas, and a controller to set the first pressure less than the second pressure.

In other features, the substrate processing system further comprises an actuator to move the showerhead pedestal vertically relative to the showerhead, and a controller to control the actuator to adjust a distance between the showerhead and the carrier ring.

In still other features, a showerhead for a substrate processing system comprises a body including a top surface, a bottom surface, and sides that define a plenum; an inlet connected to the top surface of the body to supply a purge gas to the plenum; a recessed region on the bottom surface of the body; a non-recessed region on the bottom surface of the body surrounding the recessed region; and a first plurality of through holes extending from the plenum through the bottom surface in the recessed region to disperse the purge gas onto a substrate arranged in the substrate processing system.

In other features, the body is cylindrical, and an outer edge of the recessed region tapers at an obtuse angle relative to a radius of the body toward an outer diameter of the body.

In other features, the body is cylindrical, and an outer edge of the recessed region tapers along a curve toward an outer diameter of the body.

In other features, the body is cylindrical, and the recessed region is circular in shape and has a diameter that is less than or equal to a diameter of the substrate.

In other features, the body is cylindrical, and the recessed region is circular in shape and has a diameter that is greater than or equal to a diameter of the substrate.

In other features, the body is cylindrical, and the non-recessed region is annular and has an inner diameter that is less than or equal to a diameter of the substrate.

In other features, the body is cylindrical, and the non-recessed region is annular and has an inner diameter that is greater than or equal to a diameter of the substrate.

In still other features, a system comprises the showerhead and a showerhead pedestal including a top surface defining a second plurality of through holes configured to output a plasma gas mixture. The system comprises a carrier ring arranged on the top surface of the showerhead pedestal and configured to support the substrate at a predetermined distance from the top surface of the showerhead pedestal, and the showerhead is arranged above the carrier ring. The system further comprises a spacer ring arranged on the top surface of the showerhead pedestal under the carrier ring to define a gap in which to strike the plasma. The recessed region of the showerhead is arranged above the substrate and the non-recessed region of the showerhead is arranged above the carrier ring. The plenum extends over the non-recessed region of the showerhead, and the showerhead further comprises a third plurality of through holes extending from the plenum through the bottom surface of the body in the non-recessed region to disperse the purge gas onto at least one of the substrate and the carrier ring, and the bottom surface of the body of the showerhead contacts the carrier ring.

In other features, the recessed region of the showerhead has a height and the bottom surface of the body is arranged at a second distance above the carrier ring, and the second distance is equal to the height. The body of the showerhead is cylindrical, and the recessed region of the showerhead is circular in shape and has a diameter that is less than or equal to an inner diameter of the carrier ring. The body of the showerhead is cylindrical, and the recessed region of the showerhead is circular in shape and has a diameter that is greater than or equal to an inner diameter of the carrier ring. The body of the showerhead is cylindrical, and the non-recessed region of the showerhead is annular and has an inner diameter that is less than or equal to an inner diameter of the carrier ring. The body of the showerhead is cylindrical, and the non-recessed region of the showerhead is annular and has an inner diameter that is greater than or equal to an inner diameter of the carrier ring.

In other features, the system further comprises a gas distribution system to supply the purge gas to the showerhead, and a controller to control pressure of the purge gas supplied to the showerhead. The system further comprises an actuator to move the showerhead pedestal vertically relative to the showerhead, and a controller to control the actuator to adjust a distance between the showerhead and the carrier ring.

The system further comprises an RF source configured to strike plasma between a bottom surface of the substrate and the top surface of the showerhead pedestal, and the purge gas dispersed onto a top surface of the substrate prevents processing by the plasma from occurring on the top surface of the substrate and bevel edges of the substrate. The system further comprises an RF source configured to strike plasma between a bottom surface of the substrate and the top surface of the showerhead pedestal, and the purge gas prevents processing by the plasma from occurring on a top surface of the substrate and bevel edges of the substrate without depleting processing by the plasma on the bottom surface of the substrate.

In still other features, a showerhead for a substrate processing system comprises a body including a top surface, a bottom surface, and sides; first and second inlets arranged on the body; first and second plenums arranged in the body and in fluid communication with the first and second inlets, respectively; a first plurality of through holes extending from the first plenum through the bottom surface to supply a purge gas at a first pressure onto a substrate arranged in the substrate processing system; and a second plurality of through holes extending from the second plenum through the bottom surface to supply the purge gas at a second pressure onto the substrate.

In another feature, the first pressure is less than the second pressure.

In other features, geometries of the first and second plurality of through holes are different.

In another feature, the second plenum surrounds the first plenum.

In another feature, the first plenum is circular in shape and has a diameter that is less than or equal to a diameter of the substrate.

In another feature, the first plenum is circular in shape and has a diameter that is greater than or equal to a diameter of the substrate.

In other features, the first plenum is circular in shape, and the second plenum is annular, surrounds the first plenum, and has an inner diameter that is less than or equal to a diameter of the substrate.

In other features, the first plenum is circular in shape, and the second plenum is annular, surrounds the first plenum, and has an inner diameter that is greater than or equal to a diameter of the substrate.

In other features, a system comprises the showerhead and a showerhead pedestal including a top surface defining a third plurality of through holes configured to output a plasma gas mixture. The system comprises a carrier ring arranged on the top surface of the showerhead pedestal and configured to support the substrate at a predetermined distance from the top surface of the showerhead pedestal, and the showerhead is arranged above the carrier ring. The system further comprises a spacer ring arranged on the top surface of the showerhead pedestal under the carrier ring to define a gap in which to strike the plasma.

In other features, the first plenum is arranged above the substrate and the second plenum is arranged above the carrier ring. The first plenum is circular in shape and has a diameter that is less than or equal to an inner diameter of the carrier ring. The first plenum is circular in shape and has a diameter that is greater than or equal to an inner diameter of the carrier ring. The first plenum is circular in shape; and the second plenum is annular, surrounds the first plenum, and has an inner diameter that is less than or equal to an inner diameter of the carrier ring. The first plenum is circular in shape; and the second plenum is annular, surrounds the first plenum, and has an inner diameter that is greater than or equal to an inner diameter of the carrier ring.

In other features, the system further comprises a gas distribution system to supply the purge gas to the first and second inlets, and a controller to set the first pressure less than the second pressure. The system further comprises an actuator to move the showerhead pedestal vertically relative to the showerhead, and a controller to control the actuator to adjust a distance between the showerhead and the carrier ring.

The system further comprises an RF source configured to strike plasma between a bottom surface of the substrate and the top surface of the showerhead pedestal, and the purge gas dispersed onto a top surface of the substrate prevents processing by the plasma from occurring on the top surface of the substrate and bevel edges of the substrate. The system further comprises an RF source configured to strike plasma between a bottom surface of the substrate and the top surface of the showerhead pedestal, and the purge gas prevents processing by the plasma from occurring on a top surface of the substrate and bevel edges of the substrate without depleting processing by the plasma on the bottom surface of the substrate.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1A shows an example of a substrate processing system comprising a processing chamber;

FIG. 1B shows an example of a carrier ring used in the substrate processing system;

FIG. 2 shows a portion of a semiconductor substrate indicating areas where deposition is undesirable and where deposition is prevented or minimized by the showerhead designs of the present disclosure;

FIG. 3 shows a cross-sectional view of an example of a first showerhead design according to the present disclosure;

FIG. 4 shows a cross-sectional view of an example of a second showerhead design according to the present disclosure;

FIG. 5 shows a cross-sectional view of an example of a third showerhead design according to the present disclosure; and

FIG. 6 shows a plan view of an example of inlets for gas supply to the third showerhead design according to the present disclosure.

In the drawings, reference numbers may be reused to identify similar and/or identical elements.

### DETAILED DESCRIPTION

Typically, process gases are introduced into a processing chamber from a showerhead attached to a top of the processing chamber. A substrate is arranged below the showerhead on a pedestal located at the bottom of the processing chamber. Plasma is ignited between the showerhead and the top surface of the substrate to treat the top surface of the substrate.

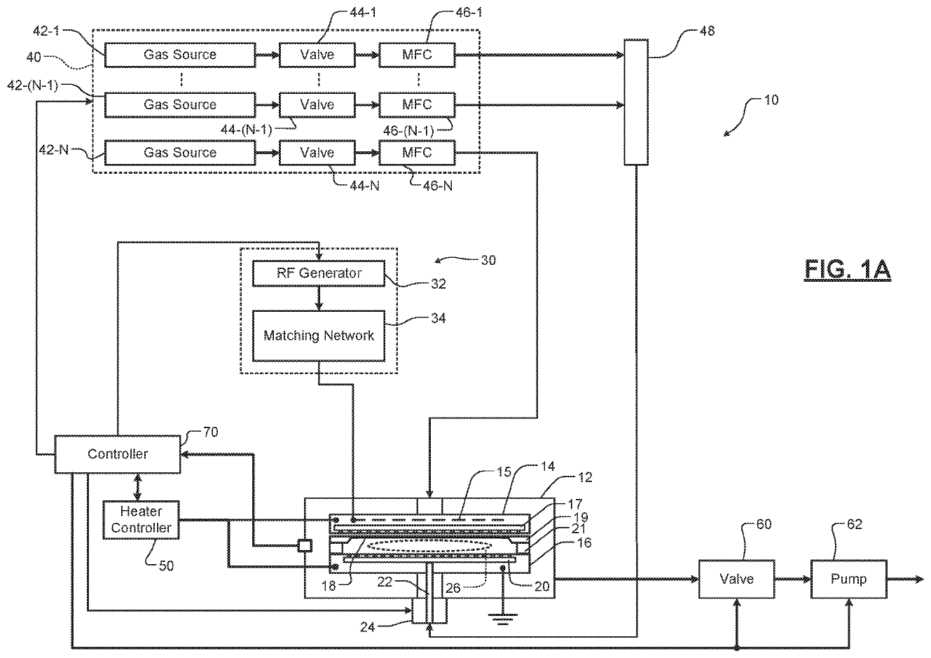

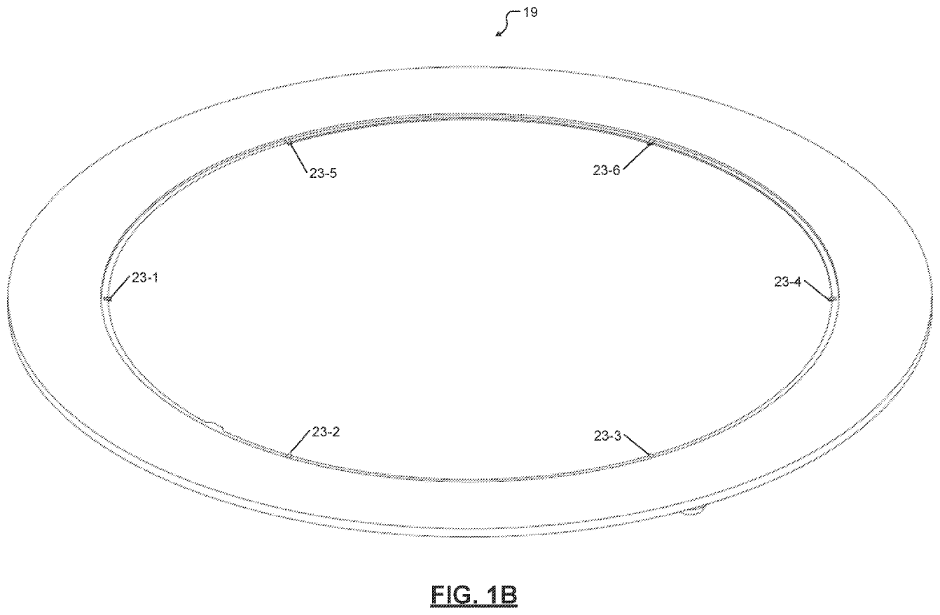

Instead, in some substrate processing systems, as shown and described below with reference to FIGS. 1A and 1B, process gases are introduced in an opposite direction. Specifically, process gases are introduced from through holes on a top surface of the pedestal towards a bottom surface of the substrate. In this sense, the pedestal functions like an inverted showerhead and is therefore called a showerhead pedestal. The substrate is held above the top surface of the showerhead pedestal by a carrier ring. The carrier ring includes tabs to support the bottom surface of the substrate. The carrier ring is arranged on a spacer ring that is arranged on the top surface of the showerhead pedestal (i.e., the spacer ring is arranged between the top surface of the showerhead pedestal and carrier ring) to define a gap between the top surface of the showerhead pedestal and the bottom surface of the substrate. Plasma is ignited in the gap to treat the bottom surface of the substrate.

In these systems, during a deposition process, material intended to be deposited only on the bottom surface (i.e., back side) of a substrate sometimes also gets deposited on the top surface (i.e., front side), edge, and bevel of the substrate. Current showerhead designs allow an unacceptable amount of deposition on the front side and bevel edge of the substrate; or in some showerhead designs, deposition on the back side of the substrate is depleted in a uniform manner at carrier ring transition, which is undesirable.

The present disclosure provides various showerhead designs and configurations to control the amount of deposition on the front side and bevel edge of the substrate without depleting the deposition on the back side of the substrate. The showerhead designs inject purge gas onto the front side of the substrate to control the amount of deposition at all three locations of the substrate: front side of bevel, edge and back side of bevel, as well as front and back side of the substrate (with no deposition desired on the front side). Specifically, the showerheads are designed to control flow (pressure and velocity) of front side purge gas. The showerhead designs do not deplete the amount of deposition on the back side of the substrate. Accordingly, the showerhead designs of the present disclosure control the amount of deposition at the three locations of the substrate without depleting the amount of deposition on the back side of the substrate.

According to a first design, a pocketed showerhead is arranged proximate to the substrate and carrier ring, leaving a small gap between the bottom of the showerhead and the top of the substrate and the carrier ring. In a second design, there is no gap between the pocketed showerhead and the carrier ring; that is, the outer diameter (OD) region of the pocketed showerhead contacts the carrier ring. Additionally, in the first and second designs, dimensions such as pocket diameter and height, the distance between substrate OD and carrier ring ID and so on are optimized to reduce or eliminate deposition on the front side and bevel edge of the substrate.

In a third design, a showerhead includes separate plenums to modulate purge gas pressures between the showerhead and the substrate, and between the showerhead and the carrier ring. These designs reduce or eliminate deposition on the front side and bevel edge of the substrate. These and other features of the showerhead designs according to the present disclosure are now described below in detail.

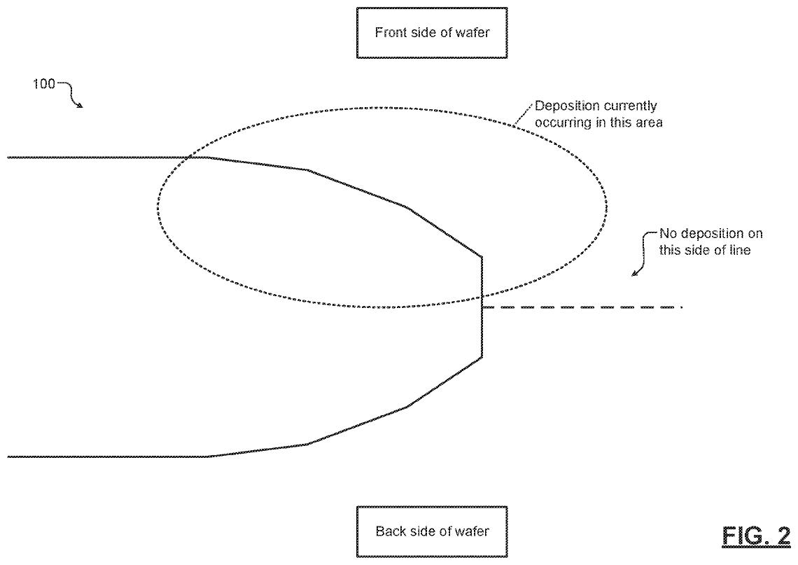

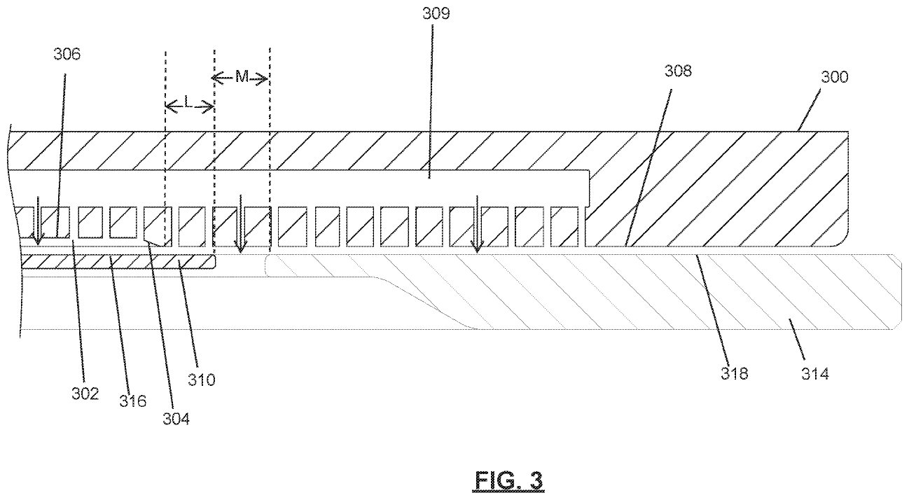

The present disclosure is organized as follows. Initially, an example of a substrate processing system including a processing chamber in which the showerheads of the present disclosure can be used is shown and described with reference to FIGS. 1A and 1B. Thereafter, the problem solved by the showerhead designs of the present disclosure is shown and described with reference to FIG. 2. Subsequently, various designs of showerheads according to the present disclosure are shown and described with reference to FIGS. 3-6.

FIG. 1A shows an example of a substrate processing system 10 including a processing chamber 12. The processing chamber 12 includes a showerhead (also called a showerhead assembly) 14 and a showerhead pedestal 16. A spacer ring 21 is arranged on the showerhead pedestal 16. A carrier ring 19 is arranged on the spacer ring 21. The carrier ring 19 includes a plurality of tabs 23-1, 23-2, . . . , and 23-6 (collectively tabs 23) that support a substrate 18 during processing.

The spacer ring 21 defines a gap between the bottom side of the substrate 18 and the top surface of the showerhead pedestal 16 in which to generate plasma. In some implementations, the spacer ring 21 may be omitted, and the carrier ring 19 can define the gap and also provide access for end effectors of a robot (not shown) to transport the carrier ring 19 in and out of the processing chamber 12.

The showerhead 14 has a cylindrical body and includes an electrode 15 and a plenum 17. The showerhead 14 includes an inlet at the top surface to receive a purge gas from a gas delivery system 40 described below. The showerhead 14 includes through holes at the bottom surface to inject the purge gas on the front (top) side of the substrate 18 to prevent deposition on the front (top) side of the substrate 18. The plenum 17 is in fluid communication with the inlet and the through holes of the showerhead 14. Additional configurations of showerheads and plenums are shown and described below with reference to FIGS. 3-6.

To introduce process gases into the processing chamber 12 for depositing material on the back (bottom) side of the substrate 18, the showerhead pedestal 16 includes a plenum 20 and a plurality through holes on a top surface of the showerhead pedestal 16. The top surface of the showerhead pedestal 16 faces the bottom side of the substrate 18 on which material is to be deposited. Process gases and vaporized chemistry are introduced via an inlet 22 at the bottom of the showerhead pedestal 16. The process gases flow from the inlet 22 into the plenum 20 and exit from the plenum 20 through the through holes on the top surface of the showerhead pedestal 16.

To generate plasma in the gap defined by the spacer ring 21 between the bottom side of the substrate 18 and the top surface of the showerhead pedestal 16, an RF generating system 30 supplies an RF voltage to the showerhead 14 (e.g., to the electrode 15), with the showerhead pedestal 16 being grounded. For example, the RF generating system 30 may include an RF voltage generator 32 that generates the RF voltage that is fed by a matching network 34 to the showerhead 14. When one or more process gases are supplied through the showerhead pedestal 16 and the RF voltage is applied across the showerhead 14 and the showerhead pedestal 16, plasma 26 is generated in the gap between the substrate 18 and the showerhead pedestal 16 to deposit materials on the bottom (backside) of the substrate 18.

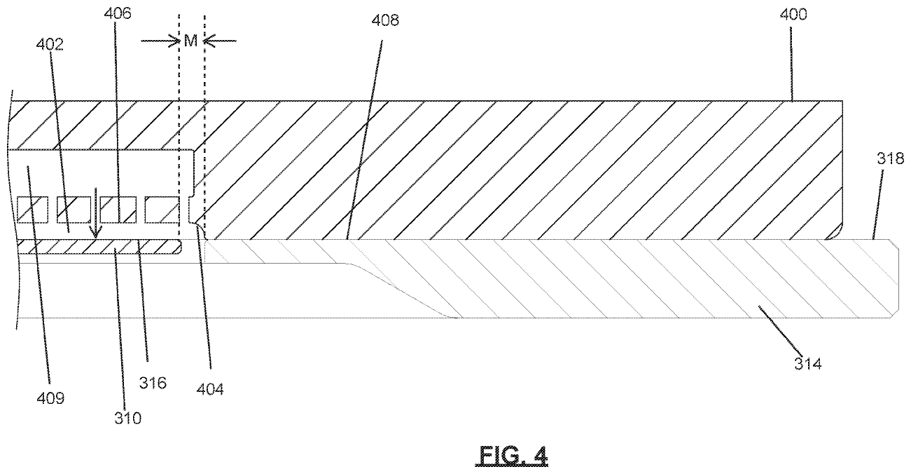

An actuator 24 moves the showerhead pedestal 16 vertically relative to the showerhead 14, which is stationary. By vertically moving the showerhead pedestal 16 relative to the showerhead 14 using the actuator 24, a gap between the showerhead 14 and the carrier ring 19 (and therefore a gap between the showerhead 14 and the substrate 18) can be changed. The gap can be adjusted dynamically during a process or between processes performed on the substrate 18. For example, in a first process, the gap can be set according to the design described below with reference to FIG. 3. For example, in a second process, the gap can be set according to the design described below with reference to FIG. 4.

The gas delivery system 40 comprises gas sources 42-1, . . . , 42-(N-1), and 42-N (collectively gas sources 42), where N is a positive integer. The gas sources 42 supply one or more process gases, precursor gases, cleaning gases, purge gases, etc. to the processing chamber 12. The gas sources 42 are connected by valves 44-1, . . . , 44-(N-1), and 44-N (collectively valves 44) and mass flow controllers 46-1, . . . , 46-(N-1), and 46-N (collectively mass flow controllers 46) to a manifold 48. An output of the manifold 48 is fed to the showerhead pedestal 16. Vaporized precursors may also be used. For some vaporized precursors, no MFC is used. The gas delivery system 40 delivers a purge gas to the showerhead 14. The gas delivery system 40 delivers process gases and vaporized precursors to the showerhead pedestal 16.

A heater controller 50 may be connected to a heater element (not shown) arranged in the showerhead pedestal 16 and in the showerhead 14. The heater controller 50 may be used to control a temperature of the showerhead 14, the showerhead pedestal 16 and the substrate 18. A valve 60 and pump 62 may be used to evacuate reactants from the processing chamber 12.

A controller 70 may control components of the substrate processing system 10. For example only, the controller 70 may control flow of process and purge gases respectively to the showerhead pedestal 16 and the showerhead 14. The controller 70 may control the actuator 24, monitor process parameters (e.g., temperature, pressure, RF power, etc.), strike and extinguish plasma, remove reactants, etc.

FIG. 2 shows a portion of a substrate 100 with its bevel edge. As indicated, deposition on the front side and bevel edge of the substrate 100 is undesirable. The showerhead designs according to the present disclosure shown and described below with reference to FIGS. 3-6 prevent or minimize the deposition on the front side and bevel edge of the substrate 100 (specifically, on the portion of the bevel edge of the substrate 100 that is above the horizontal dashed line).

FIGS. 3-6 show various designs of showerheads. These designs control pressure and velocity of the purge gas injected from the showerhead onto the front side of the substrate to control the amount of deposition on the front side of bevel, edge and back side of bevel, as well as front and back side of the substrate (with no deposition desired on the front side). In these designs, as the velocity of the purge gas injected from the showerhead onto the front side of the substrate increases, the concentration of the deposition decreases on the front side of the substrate, front side of bevel, and edge and back side of bevel. The deposition on the backside of the substrate is not depleted.

These designs are optimized to achieve the above objectives over a range of variations in parameters such as showerhead and pedestal temperatures, substrate position, and the type, pressure, and flow rate of the purge gas used. These designs are also optimized according to the substrate diameter. That is, the gap between the showerhead and the carrier ring, and other parameters including pocket dimensions, distance between the substrate OD and the carrier ring ID, and purge gas pressures described below are optimized according to the substrate diameter. Further, one design may be used in one process while another design may be used in another process.

In some applications, the showerheads are made of a ceramic material and are not made of a metal because the ceramic material can withstand relatively high process temperatures (e.g., about 550 degrees Celsius). In applications where process temperatures are much lower, the showerheads are made of metal (e.g., aluminum).

FIG. 3 shows a first showerhead 300 according to the present disclosure. The showerhead 300 includes a pocket 302, which is a circular recessed region at the bottom of the showerhead 300. An outer edge 304 of the pocket 302 is shown as tapering at an obtuse angle relative to a radius of the pocket 302 toward the OD of the showerhead 300 for example only. In another implementation, the outer edge 304 may taper towards the OD of the showerhead 300 along a curve (e.g., as shown in FIG. 4) instead of tapering at an angle. A distance between an upper edge 306 of the pocket 302 and a bottom edge 308 of the showerhead 300 is called a height “h” of the pocket 302.

The showerhead 300 includes a plenum 309 to inject a purge gas from through holes at the bottom edge 308 of the showerhead 300 onto a front side of a substrate 310 as indicated by downward pointing arrows from the bottom of the showerhead 300. The through holes are arranged in the pocketed region of the showerhead 300 as well in the outer un-recessed region of the showerhead 300 surrounding the pocket 302.

The substrate 310 is arranged on a carrier ring 314, which is arranged along with a spacer ring (e.g., element 21 shown in FIG. 1A) on a showerhead pedestal (e.g., showerhead pedestal 16 shown in FIG. 1A) as described above with reference to FIG. 1A. Plasma is struck in a gap defined under the substrate 210 by the spacer ring when process gases are supplied through the showerhead pedestal and RF power is supplied across the showerhead 300 and the showerhead pedestal as described above with reference to FIG. 1A.

A top surface 316 of the substrate 310 and a top surface 318 of the carrier ring 314 are coplanar and are arranged at a distance “d” from the bottom edge 308 of the showerhead 300. In one implementation, d=h. For example only, for a 300 mm substrate, d=h=0.5 mm. In other implementations, d>h or d<h. In some implementations, d may be varied by moving the showerhead pedestal vertically as described above with reference to FIG. 1A.

A distance between the outer edge 304 of the pocket 302 (i.e., the end of the pocket 302) and the OD of the substrate 310 is denoted by L. A distance between the OD of the substrate 310 and the ID of the carrier ring 314 is denoted by M. For example only, for a 300 mm substrate, L=3 mm, and M=6 mm. In some implementations, the ID of carrier ring 314 may be selected such that the ID of carrier ring 314 can be closer to the OD of the substrate 310 (e.g., M can be less than 6 mm).

The value of L determines the velocity of the purge gas. For example, the pressure of the purge gas under the pocket 302 is less than the purge gas pressure in the outer region surrounding the pocket 302. In general, as L decreases, the purge gas pressure and velocity increase in the outer region surrounding the pocket 302 (i.e., from the outer edge 304 of the pocket 302 towards to the OD of the substrate 310). The higher purge gas pressure and velocity reduce or eliminate deposition at the front side of the substrate 310, front side of bevel, and edge and back side of bevel.

Accordingly, the value of L can be optimized by selecting the diameter of the pocket 302. For example, as the diameter of the pocket 302 increases, the pocket 302 extends radially outwards towards the OD of the substrate 310 (i.e., towards the OD of the showerhead 300), and L decreases. Conversely, as the diameter of the pocket 302 decreases, the pocket 302 extends radially inwards towards the center of the substrate 310 (i.e., towards the center of the showerhead 300), and L increases. A controller (e.g., element 70 shown in FIG. 1A) controls the pressure at which the showerhead 300 injects the purge gas. The pressure also controls the velocity of the purge gas.

FIG. 4 shows a second showerhead 400 according to the present disclosure. The substrate 310, the carrier ring 314, and the spacer ring are arranged on the showerhead pedestal as described above with reference to FIG. 3. Process gases are supplied through the showerhead pedestal and plasma is struck as described above with reference to FIG. 3.

The showerhead 400 includes a pocket 402, which is a circular recessed region at the bottom of the showerhead 400. An outer edge 404 of the pocket 402 is shown as tapering along a curve toward the OD of the showerhead 400 for example only. In another implementation, the outer edge 404 may taper at an obtuse angle relative to a radius of the pocket 402 toward the OD of the showerhead 400 (e.g., as shown in FIG. 3). A distance between an upper edge 406 of the pocket 402 and a bottom edge 408 of the showerhead 400 is called a height “h” of the pocket 402. For example only, for a 300 mm substrate, h=1 mm.

The showerhead 400 includes a plenum 409 to inject a purge gas from through holes at the bottom edge 408 of the showerhead 400 onto the front side of the substrate 310 as indicated by downward pointing arrows from the bottom of the showerhead 400. The through holes are arranged in the pocketed region of the showerhead 400. The outer un-recessed bottom portion of the showerhead 400 surrounding the pocket 402 contacts the top surface 318 of the carrier ring 314. That is, there is no gap between the outer un-recessed bottom portion of the showerhead 400 surrounding the pocket 402 and the top surface 318 of the carrier ring 314.

The top surface 316 of the substrate 310 and the top surface 318 of the carrier ring 314 are coplanar. The top surface 318 of the carrier ring is in contact with the bottom edge 408 of the showerhead 400. The top surface 316 of the substrate 310 is separated from the upper edge 406 of the pocket 402 by the height “h” of the pocket 402.

The pocket 402 is shown as having a greater diameter than the substrate 310 for example only. In some implementations, the pocket 402 can have a smaller diameter than the substrate 310. The pocket 402 is also shown as having the diameter as the ID of the carrier ring 314 for example only. In some implementations, the pocket 402 can extend radially further towards the OD of the showerhead 400; that is, the diameter of the pocket 402 can be greater than the ID of the carrier ring 314.

The purge gas pressure and velocity are optimized to reduce or eliminate deposition at the front side of the substrate 310, front side of bevel, and edge and back side of bevel. Further, the distance M between the OD of the substrate 310 and the ID of the carrier ring 314 can be optimized to reduce or eliminate deposition at the front side of the substrate 310, front side of bevel, and edge and back side of bevel. For example, in one implementation, the ID of carrier ring 314 may be selected such that the ID of carrier ring 314 can be closer to the OD of the substrate 310 (i.e., M is decreased). For example, in another implementation, the ID of carrier ring 314 may be selected such that the ID of carrier ring 314 can be farther from the OD of the substrate 310 (i.e., M is increased). A controller (e.g., element 70 shown in FIG. 1A) controls the pressure at which the showerhead 400 injects the purge gas. The pressure also controls the velocity of the purge gas.

In each of the first and second showerhead designs 300, 400, the body of the showerhead is cylindrical, and the recessed region (i.e., the pocket) of the showerhead is circular in shape. In one implementation, a diameter of the recessed region is less than or equal to a diameter of the substrate. In another implementation, the diameter of the recessed region is greater than or equal to the diameter of the substrate. In another implementation, the diameter of the recessed region is less than or equal to an inner diameter of the carrier ring. In another implementation, the diameter of the recessed region is greater than or equal to the inner diameter of the carrier ring.

Further, in each of the first and second showerhead designs 300, 400, the non-recessed region of the showerhead is annular and surrounds the recessed region. In one implementation, an inner diameter of the non-recessed region is less than or equal to the diameter of the substrate. In another implementation, the inner diameter of the non-recessed region is greater than or equal to the diameter of the substrate. In another implementation, the inner diameter of the non-recessed region is less than or equal to the inner diameter of the carrier ring. In another implementation, the inner diameter of the non-recessed region is greater than or equal to the inner diameter of the carrier ring.

The various diameter configurations described above are not mutually exclusive. That is, any suitable and feasible combination of the various diameter configurations described above may be used.

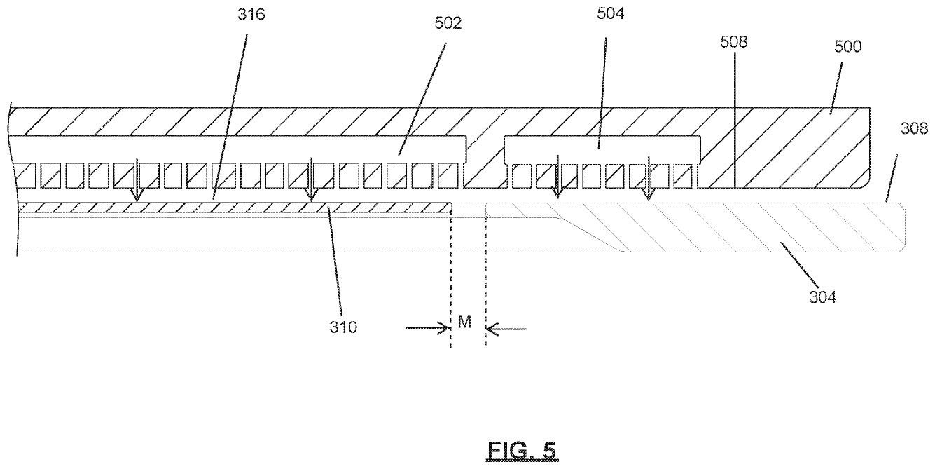

FIG. 5 shows a third showerhead 500 according to the present disclosure. The substrate 310, the carrier ring 314, and the spacer ring are arranged on the showerhead pedestal as described above with reference to FIG. 3. Process gases are supplied through the showerhead pedestal and plasma is struck as described above with reference to FIG. 3.

The showerhead 500 does not include a pocket. The showerhead 500 includes two plenums: a first plenum 502 that is circular and a second plenum 504 that is annular. The second plenum 504 surrounds the first plenum 502. A diameter of the first plenum 502 is less than an inner diameter (ID) of the second plenum 504. The plenums 502, 504 are separate and not interconnected.

Each of the plenums 502, 504 injects a purge gas through respective through holes at the bottom of the showerhead 500 onto the front side of the substrate 310 as indicated by downward pointing arrows from the bottom of the showerhead 500. The first plenum 502 provides the purge gas at a first pressure from a first set of through holes arranged on a first (inner) bottom portion of the showerhead 500 that is above and covering the front side of the substrate 310. The second plenum 504 provides the purge gas at a second pressure from a second set of through holes arranged on a second (outer) bottom portion of the showerhead 500 that is above and covering an area between the ID of the carrier ring 314 and the OD of the showerhead 500. The first pressure is less than the second pressure to reduce or eliminate deposition at the front side of the substrate 310, front side of bevel, and edge and back side of bevel.

The purge gas can be supplied at different pressures through the first and second plenums 502, 504 using one or more of the following schemes. For example, the number of the through holes per unit area (called through-hole density) of the plenums 502, 504 can be different. Accordingly, when the purge gas is supplied to the plenums 502, 504 at a predetermined pressure and/or flow rate, the purge gas is dispersed at a different pressure through the first set of through holes of the first plenum 502 than through the second set of through holes of the second plenum 504.

Alternatively or additionally, the size of the through holes associated with the first and second plenums 502, 504 can be different. Accordingly, when the purge gas is supplied to the plenums 502, 504 at a predetermined pressure and/or flow rate, the purge gas is dispersed at a different pressure through the first set of through holes of the first plenum 502 than through the second set of through holes of the second plenum 504.

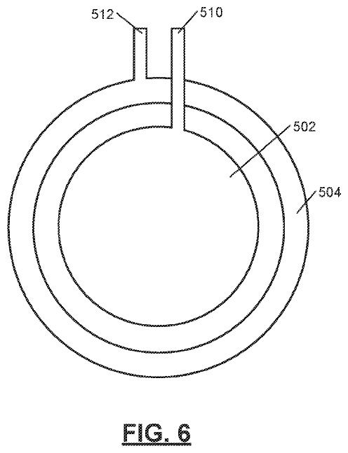

Alternatively or additionally, as shown in FIG. 6, two separate inlets 510, 512 are provided in the showerhead 500. Each of the plenums 502, 504 is in fluid communication with respective inlets 510, 512. In one implementation, each of the inlets 510, 512 receives the purge gas from the same gas source (e.g., gas source 42N shown in FIG. 1A) via two separate valves (e.g., valve 44N and an additional valve, 44(N+1)) connected to the gas source 42N and via two separate MFC's (e.g., MFC 46N and an additional MFC, 44(N+1)) respectively connected to the two separate valves. The controller 70 controls the different pressures in the plenums 502, 504 by controlling the two separate valves and the two separate MFC's.

In another implementation, each of the inlets 510, 512 receives the purge gas from two separate gas sources (e.g., gas source 42N and an additional gas source 42(N+1)) via two separate valves (e.g., valve 44N and an additional valve, 44(N+1)) respectively connected to the two separate gas sources and via two separate MFC's (e.g., MFC 46N and an additional MFC, 44(N+1)) respectively connected to the two separate valves. The controller 70 controls the different pressures in the plenums 502, 504 by controlling the two separate valves and the two separate MFC's.

In general, the diameter of the first plenum 502 can be greater than, equal to, or less than the diameter of the substrate 310. Alternatively or additionally, the ID of the second plenum 504 can be greater than, equal to, or less than the ID of the carrier ring 314 (or the OD of the substrate 310).

More generally, the first plenum 502 is circular in shape. In one implementation, a diameter of the first plenum 502 is less than or equal to a diameter of the substrate 310. In another implementation, the diameter of the first plenum 502 is greater than or equal to the diameter of the substrate 310. In another implementation, the diameter of the first plenum 502 is less than or equal to an inner diameter of the carrier ring 314. In another implementation, the diameter of the first plenum 502 is greater than or equal to the inner diameter of the carrier ring 314.

Further, the second plenum 504 is annular and surrounds the first plenum 502. In one implementation, an inner diameter of the second plenum 504 is less than or equal to the diameter of the substrate 310. In another implementation, the inner diameter of the second plenum 504 is greater than or equal to the diameter of the substrate 310. In another implementation, the inner diameter of the second plenum 504 is less than or equal to the inner diameter of the carrier ring 314. In another implementation, the inner diameter of the second plenum 504 is greater than or equal to the inner diameter of the carrier ring 314.

The various diameter configurations described above are not mutually exclusive. That is, any suitable and feasible combination of the various diameter configurations described above may be used.

The top surface 316 of the substrate 310 and the top surface 318 of the carrier ring 314 are coplanar and are arranged at a distance “d” from a bottom edge 508 of the showerhead 500. For example only, for a 300 mm substrate, d=1 mm. In some implementations, d may be varied by moving the showerhead pedestal vertically as described above with reference to FIG. 1A.

The distance M between the OD of the substrate 310 and the ID of the carrier ring 314 can be optimized to reduce or eliminate deposition at the front side of the substrate 310, front side of bevel, and edge and back side of bevel. For example, in one implementation, the ID of carrier ring 314 may be selected such that the ID of carrier ring 314 can be closer to the OD of the substrate 310 (i.e., M is decreased). For example, in another implementation, the ID of carrier ring 314 may be selected such that the ID of carrier ring 314 can be farther from the OD of the substrate 310 (i.e., M is increased).

In some applications, the showerhead 500 can include the pocket 302 or the pocket 402 shown in FIGS. 3 and 4, respectively, under the first plenum 502. Alternatively or additionally, the showerhead 500 can include an annular pocket under the second plenum 504, where an inner edge of the pocket tapers at an obtuse angle or along a curve toward the ID of the carrier ring 314.

In the above designs, all of the described dimensions (e.g., diameters, distances, gaps, heights, pressures, etc.) can be varied and optimized either by changing only one of the dimensions or by changing a plurality of the dimensions in combination to reduce or eliminate deposition at the front side of the substrate 310, front side of bevel, and edge and back side of bevel. Further, the dimensions can be varied and optimized such that the deposition on the backside of the substrate 310 is not depleted.

The foregoing description is merely illustrative in nature and is not intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process.

In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control.

Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A showerhead for a substrate processing system comprising:
a body including a top surface, a bottom surface, and sides that define a plenum;
an inlet connected to the top surface of the body to supply a purge gas to the plenum;
a recessed region on the bottom surface of the body;
a non-recessed region on the bottom surface of the body surrounding the recessed region; and
a first plurality of through holes extending from the plenum through the bottom surface in the recessed region to disperse the purge gas onto a substrate arranged in the substrate processing system.

2. The showerhead of claim 1 wherein the body is cylindrical and wherein an outer edge of the recessed region tapers at an obtuse angle relative to a radius of the body toward an outer diameter of the body.

3. The showerhead of claim 1 wherein the body is cylindrical and wherein an outer edge of the recessed region tapers along a curve toward an outer diameter of the body.

4. The showerhead of claim 1 wherein the body is cylindrical and the recessed region is circular in shape and has a diameter that is less than or equal to a diameter of the substrate.

5. The showerhead of claim 1 wherein the body is cylindrical and the recessed region is circular in shape and has a diameter that is greater than or equal to a diameter of the substrate.

6. The showerhead of claim 1 wherein the body is cylindrical and the non-recessed region is annular and has an inner diameter that is less than or equal to a diameter of the substrate.

7. The showerhead of claim 1 wherein the body is cylindrical and the non-recessed region is annular and has an inner diameter that is greater than or equal to a diameter of the substrate.

8. A system comprising:
the showerhead of claim 1;
a showerhead pedestal including a top surface defining a second plurality of through holes configured to output a plasma gas mixture; and
a carrier ring arranged on the top surface of the showerhead pedestal and configured to support the substrate at a predetermined distance from the top surface of the showerhead pedestal,
wherein the showerhead is arranged above the carrier ring.

9. The system of claim 8 further comprising a spacer ring arranged on the top surface of the showerhead pedestal under the carrier ring to define a gap in which to strike the plasma.

10. The system of claim 8 wherein the recessed region of the showerhead is arranged above the substrate and the non-recessed region of the showerhead is arranged above the carrier ring.

11. The system of claim 8 wherein the plenum extends over the non-recessed region of the showerhead and the showerhead further comprises a third plurality of through holes extending from the plenum through the bottom surface of the body in the non-recessed region to disperse the purge gas onto at least one of the substrate and the carrier ring.

12. The system of claim 8 wherein the bottom surface of the body of the showerhead contacts the carrier ring.

13. The system of claim 8 wherein the recessed region of the showerhead has a height and the bottom surface of the body is arranged at a second distance above the carrier ring, wherein the second distance is equal to the height.

14. The system of claim 8 wherein the body of the showerhead is cylindrical and the recessed region of the showerhead is circular in shape and has a diameter that is less than or equal to an inner diameter of the carrier ring.

15. The system of claim 8 wherein the body of the showerhead is cylindrical and the recessed region of the showerhead is circular in shape and has a diameter that is greater than or equal to an inner diameter of the carrier ring.

16. The system of claim 8 wherein the body of the showerhead is cylindrical and the non-recessed region of the showerhead is annular and has an inner diameter that is less than or equal to an inner diameter of the carrier ring.

17. The system of claim 8 wherein the body of the showerhead is cylindrical and the non-recessed region of the showerhead is annular and has an inner diameter that is greater than or equal to an inner diameter of the carrier ring.

18. The system of claim 8 further comprising:
a gas distribution system to supply the purge gas to the showerhead; and
a controller to control pressure of the purge gas supplied to the showerhead.

19. The system of claim 8 further comprising:
an actuator to move the showerhead pedestal vertically relative to the showerhead; and
a controller to control the actuator to adjust a distance between the showerhead and the carrier ring.

20. The system of claim 8 further comprising:
an RF source configured to strike plasma between a bottom surface of the substrate and the top surface of the showerhead pedestal,
wherein the purge gas dispersed onto a top surface of the substrate prevents processing by the plasma from occurring on the top surface of the substrate and bevel edges of the substrate.

21. The system of claim 8 further comprising:
an RF source configured to strike plasma between a bottom surface of the substrate and the top surface of the showerhead pedestal,
wherein the purge gas prevents processing by the plasma from occurring on a top surface of the substrate and bevel edges of the substrate without depleting processing by the plasma on the bottom surface of the substrate.
